(19) United States
(12) Patent Application Publication
(10) Pub. No.: US 2024/0421121 A1
(43) Pub. Date: Dec. 19, 2024

(54) SEMICONDUCTOR DEVICE

(71) Applicant: Kioxia Corporation, Tokyo (JP)

(72) Inventors: Masayuki MIURA, Ota Tokyo (JP); Kazuma HASEGAWA, Fujisawa Kanagawa (JP); Hideko MUKAIDA, Taito Tokyo (JP); Kana KUDO, Yokohama Kanagawa (JP)

(73) Assignee: Kioxia Corporation, Tokyo (JP)

(21) Appl. No.: 18/734,204

(22) Filed: Jun. 5, 2024

(30) Foreign Application Priority Data
Jun. 15, 2023 (JP) 2023-098725

(51) Int. Cl. H01L 25/065; H10B 80/00

(52) U.S. Cl. CPC H01L 25/0652; H10B 80/00; H01L 2225/06506; H01L 2225/0651; H01L 2225/06562; H01L 2225/06586

(57) ABSTRACT

A semiconductor device according to an embodiment includes a substrate, a first stack, a second stack, a first bonding layer, a second bonding layer, a first wire, and a second wire. The first stack has a plurality of first semiconductor chips. The second stack has a plurality of second semiconductor chips. The first bonding layer is provided at a lower part of each of the plurality of first semiconductor chips. The second bonding layer is provided at a lower part of each of the plurality of second semiconductor chips. The first wire electrically connects the first semiconductor chips and the second semiconductor chips to one another. The second wire electrically connects the substrate and the second semiconductor chips. The first bonding layer provided at the lower part of the first semiconductor chip in a lowest stage has a thickness different from the thickness of the other first bonding layers.

### CROSS REFERENCE TO RELATED APPLICATIONS

This application is based upon and claims the benefit of priority from the prior Japanese Patent Application No. 2023-098725, filed on Jun. 15, 2023, the entire contents of which are incorporated herein by reference.

### FIELD

The embodiments of the present invention relate to a semiconductor device.

### BACKGROUND

In a package structure of a semiconductor device, semiconductor chips whose ratio (aspect ratio) of the width of long sides to the width of the short sides is high are mounted in some cases. It is difficult in some cases to appropriately dispose the semiconductor chips having a high aspect ratio in the semiconductor package.

### BRIEF DESCRIPTION OF THE DRAWINGS

FIG. 1 is a cross sectional view illustrating an example of the configuration of a semiconductor device according to a first embodiment;

FIG. 2 is a top view illustrating the example of the configuration of the semiconductor device according to the first embodiment;

FIG. 3 is a cross sectional view illustrating an example of the configuration of a semiconductor device according to a first comparative example of the first embodiment;

FIG. 4 is a cross sectional view illustrating an example of the configuration of a semiconductor device according to a second comparative example of the first embodiment;

FIG. 5 is a cross sectional view illustrating an example of the configuration of a semiconductor device according to a first modification of the first embodiment;

FIG. 6 is a cross sectional view illustrating an example of the configuration of a semiconductor device according to a second embodiment;

FIG. 7 is a top view illustrating the example of the configuration of the semiconductor device according to the second embodiment;

FIG. 8 is a cross sectional view illustrating an example of the configuration of a semiconductor device according to a first modification of the second embodiment;

FIG. 9 is a top view illustrating the example of the configuration of the semiconductor device according to the first modification of the second embodiment;

FIG. 10 is a top view illustrating an example of the configuration of a semiconductor device according to a second modification of the second embodiment;

FIG. 11 is a top view illustrating an example of connection of bonding wires in the second modification of the second embodiment;

FIG. 12 is a cross sectional view illustrating an example of the configuration of a semiconductor device according to a third modification of the second embodiment;

FIG. 13 is a cross sectional view illustrating an example of the configuration of a semiconductor device according to a fourth modification of the second embodiment;

FIG. 14 is a cross sectional view illustrating an example of the configuration of a semiconductor device according to a fifth modification of the second embodiment;

FIG. 15 is a cross sectional view illustrating an example of the configuration of a semiconductor device according to a sixth modification of the second embodiment;

FIG. 16 is a cross sectional view illustrating an example of the configuration of a semiconductor device according to a seventh modification of the second embodiment;

FIG. 17 is a cross sectional view illustrating an example of the configuration of a semiconductor device according to an eighth modification of the second embodiment;

FIG. 18 is a cross sectional view illustrating an example of the configuration of a semiconductor device according to a third embodiment;

FIG. 19 is a top view illustrating the example of the configuration of the semiconductor device according to the third embodiment;

FIG. 20 is a cross sectional view illustrating an example of the configuration of a semiconductor device according to a first modification of the third embodiment;

FIG. 21 is a cross sectional view illustrating an example of the configuration of a semiconductor device according to a second modification of the third embodiment;

FIG. 22 is a cross sectional view illustrating an example of the configuration of a semiconductor device according to a third modification of the third embodiment;

FIG. 23 is a cross sectional view illustrating an example of the configuration of a semiconductor device according to a fourth modification of the third embodiment; and

FIG. 24 is a cross sectional view illustrating an example of the configuration of a semiconductor device according to a fifth modification of the third embodiment.

### DETAILED DESCRIPTION

Embodiments will now be explained with reference to the accompanying drawings. The present invention is not limited to the embodiments. It should be noted that the drawings are schematic or conceptual, and the relationship between the thickness and the width in each element and the ratio among the dimensions of elements do not necessarily match the actual ones. Even if two or more drawings show the same portion, the dimensions and the ratio of the portion may differ in each drawing. In the present specification and the drawings, elements identical to those described in the foregoing drawings are denoted by like reference characters and detailed explanations thereof are omitted as appropriate.

A semiconductor device according to the present embodiment includes a substrate, a first stack, a second stack, a first bonding layer, a second bonding layer, a first wire, and a second wire. The substrate has a first surface. The first stack has a plurality of first semiconductor chips. The second stack is provided at a position different from the first stack in an in-plane direction of the first surface and has a plurality of second semiconductor chips. The first bonding layer is provided at a lower part of each of the plurality of first semiconductor chips. The second bonding layer is provided at a lower part of each of the plurality of second semiconductor chips. The first wire electrically connects the first semiconductor chips and the second semiconductor chips to one another. The second wire electrically connects the substrate and the second semiconductor chips. The first bonding layer provided at the lower part of the first semiconductor chip in a lowest stage has a thickness different from the thickness of the other first bonding layers.

### First Embodiment

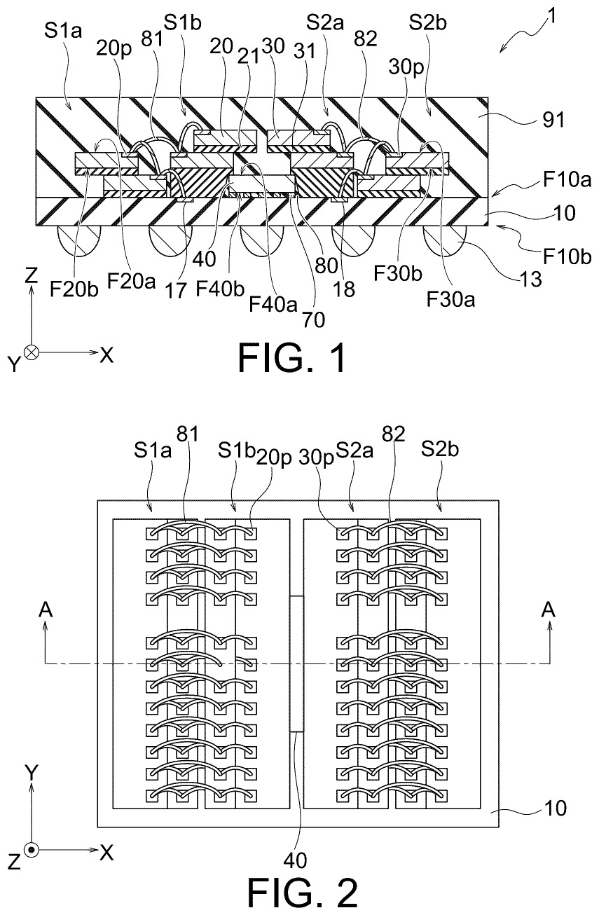

FIG. 1 is a cross sectional view illustrating an example of the configuration of a semiconductor device 1 according to a first embodiment. FIG. 2 is a top view illustrating the example of the configuration of the semiconductor device 1 according to the first embodiment. Line A-A in FIG. 2 indicates a cross section corresponding to the cross sectional view of FIG. 1.

The semiconductor device 1 includes a wiring substrate 10, stacks S1a, S1b, S2a, S2b, a semiconductor chip 40, bonding wires 81, 82, and a sealing resin 91. The semiconductor device 1 is, for example, a packaged NAND type flash memory.

Note that FIG. 1 illustrates an X direction and a Y direction parallel to a front surface of a substrate (the wiring substrate 10) and orthogonal to each other, and a Z direction orthogonal to the front surface of the substrate (the wiring substrate 10). In the present specification, the positive Z direction is an upward direction, and the negative Z direction is a downward direction. The negative Z direction may or may not be aligned with the direction of gravity.

The wiring substrate 10 may be a printed circuit board or an interposer including wiring layers (not illustrated) and insulating layers (not illustrated). A low resistance metal such as copper (Cu), nickel (Ni), or alloy thereof is used as the wiring layers. An insulating material such as glass epoxy resin is used as the insulating layers. The wiring substrate 10 may include a multi-layer wiring structure formed by stacking a plurality of wiring layers and a plurality of insulating layers. The wiring substrate 10 may include a penetration electrode penetrating through front and back surfaces thereof like an interposer.

A solder resist layer provided on a wiring layer is provided on the front surface (a surface F10a) of the wiring substrate 10. The solder resist layer is also used for an insulating layer for protecting the wiring layer and for preventing short-circuit defect. Pads 17, 18 are provided on the front surface of the wiring substrate 10. The pads 17, 18 are wiring layers exposed through the solder resist layer. The pad 17 is electrically connected to the stack S1a. The pad 18 is electrically connected to the stack S2b. The pads 17, 18 are, for example, gold (Au) plated electrodes. A pad (not illustrated) to be connected to a metallic material 70 which will be described later is also provided on the front surface of the wiring substrate 10.

A solder resist layer provided on a wiring layer is provided on the back surface (a surface F10b) of the wiring substrate 10. Connection bumps 13 are provided on the wiring layer exposed through the solder resist layer. The connection bumps 13 are provided to electrically connect non-illustrated other components to the wiring substrate 10.

The stacks S1a, S1b each have semiconductor chips 20 and bonding layers 21. The bonding layer 21 is, for example, a die attachment film (DAF) or non conductive paste (NCP). The stack S1a is a stack in which the plurality of semiconductor chips 20 are stacked while being displaced in a direction (for example, the negative X direction) orthogonal to a stacked direction (the Z direction). The stack S1b is a stack in which the plurality of semiconductor chips 20 are stacked while being displaced in a direction (for example, the positive X direction) orthogonal to the stacked direction (the Z direction). The stacks S1a, S1b are provided on the surface F10a.

The semiconductor chip 20 is, for example, a memory chip including a NAND type flash memory. The semiconductor chip 20 has a semiconductor element (not illustrated) on its front surface (upper surface, a surface F20a). The semiconductor element may be, for example, a memory cell array and its peripheral circuit (complementary metal oxide semiconductor (CMOS) circuit). The memory cell array may be a stereoscopic memory cell array in which a plurality of memory cells are three-dimensionally disposed. In FIG. 1, the stacks S1a, S1b each have the semiconductor chips 20 as two stacked memory chips. However, the number of stacked semiconductor chips may be three or more.

The stacks S2a, S2b each have semiconductor chips 30 and bonding layers 31. The bonding layer 31 is, for example, a die attachment film (DAF) or non conductive paste (NCP). The stack S2a is a stack in which the plurality of semiconductor chips 30 are stacked while being displaced in the direction (for example, the negative X direction) orthogonal to the stacked direction (the Z direction). The stack S2b is a stack in which the plurality of semiconductor chips 30 are stacked while being displaced in the direction (for example, the positive X direction) orthogonal to the stacked direction (the Z direction). The stacks S2a, S2b are provided at positions in the X direction substantially parallel to the surface F10a with respect to the positions of the stacks S1a, S1b on the surface F10a.

The semiconductor chip 30 is, for example, a memory chip including a NAND type flash memory. The semiconductor chip 30 has a semiconductor element (not illustrated) on its front surface (upper surface, a surface F30a). The semiconductor element may be, for example, a memory cell array and its peripheral circuit (CMOS circuit). The memory cell array may be a stereoscopic memory cell array in which a plurality of memory cells are three-dimensionally disposed. In FIG. 1, the stacks S1a, S1b each have the semiconductor chips 30 as two stacked memory chips. However, the number of stacked semiconductor chips may be three or more.

The semiconductor chip 40 is, for example, a controller chip that controls a memory chip. A non-illustrated semiconductor element is provided on a surface F40b of the semiconductor chip 40 facing the wiring substrate 10. The semiconductor element may be, for example, a complementary metal oxide semiconductor (CMOS) circuit constituting a controller. An electrode pillar (not illustrated) electrically connected to the semiconductor element is provided on the surface F40b which is a back surface (lower surface) of the semiconductor chip 40. A low resistance metallic material such as copper, nickel, or alloy thereof is used as the electrode pillar.

The semiconductor chip 40 is provided on the surface F10a. The semiconductor chip 40 is provided between the stacks S1a and S2b, for example.

The metallic material 70 is provided around the electrode pillar as a connection bump. The electrode pillar is electrically connected through the metallic material 70 to the wiring layer exposed at an opening part of the solder resist layer. A low resistance metallic material such as solder, silver, or copper is used as the metallic material 70. The metallic material 70 electrically connects the electrode pillar of the semiconductor chip 40 and the wiring layer of the wiring substrate 10.

A resin layer 80 is provided in a region around the metallic material 70 and a region between the semiconductor chip 40 and the wiring substrate 10. The resin layer 80 is, for example, cured underfill resin and covers and protects the circumference of the semiconductor chip 40.

The bonding wire 81 is connected to the wiring substrate 10 and optional pads of the semiconductor chips 20. The bonding wire 82 is connected to the wiring substrate 10 and optional pads of the semiconductor chips 30. The bonding wires 81, 82 are, for example, gold (Au) wires. For the connection through the bonding wires 81, 82, the semiconductor chips 20, 30 are stacked while being displaced as corresponding to pads 20p, 30p.

The sealing resin 91 seals the stacks S1a, S1b, S2a, and S2b, the semiconductor chip 40, the bonding wires 81, 82, and the like. Accordingly, in the semiconductor device 1, the stacks S1a, S1b, S2a, and S2b and the semiconductor chip 40 are constituted as one semiconductor package on the wiring substrate 10.

Details of the configuration of the stacks S1a, S1b, S2a, and S2b and the semiconductor chip 40 will be described below.

As Illustrated in FIG. 2, the semiconductor chip 20 is disposed such that its short sides are substantially parallel to the X direction and its long sides are substantially parallel to the Y direction. Accordingly, the plurality of semiconductor chips 20 are stacked while being displaced in the short side direction of the semiconductor chips 20. The semiconductor chip 20 has an elongated shape when viewed from above. The semiconductor chip 20 may be disposed such that its short sides are substantially parallel to the Y direction and its long sides are substantially parallel to the X direction.

As Illustrated in FIG. 1, the stacks S1a, S1b are disposed to be aligned in the short side direction of the semiconductor chips 20.

Each of the stacks S1a, S1b has the semiconductor chips 20 stacked in two stages. The semiconductor chips 20 in the lowest stages of the stacks S1a, S1b are provided at different positions on the surface F10a. Note that the number of the stacked semiconductor chips 20 may be three or more.

The plurality of bonding wires 81 electrically connect the plurality of semiconductor chips 20 to one another. The stacks S1a, S1b are electrically connected to each other through the bonding wires 81. The bonding wires 81 unicursally connect the plurality of semiconductor chips 20 to one another, for example.

The thickness of the bonding layer 21 provided at the lower part of the semiconductor chip 20 in the lowest stage of the stack S1b is different from the thickness of the other bonding layers 21. More specifically, the bonding layer 21 provided at the lower part of the semiconductor chip 20 in the lowest stage of the stack S1b is thicker than the other bonding layers 21.

The bonding layer 21 provided at the lower part of the semiconductor chip 20 in the lowest stage of the stack S1b covers at least part of the semiconductor chip 40. Accordingly, the stack S1b and the semiconductor chip 40 can be disposed close to each other, and the package area can be made smaller.

The bonding layer 21 provided at the lower part of the semiconductor chip 20 in the lowest stage of the stack S1b covers at least part of the bonding wire 81 that electrically connects the semiconductor chip 20 in the lowest stage of the stack S1a to the wiring substrate 10. Accordingly, the stacks S1a, S1b can be disposed close to each other, and the package area can be made smaller.

As Illustrated in FIG. 2, the semiconductor chip 30 is disposed such that its short sides are substantially parallel to the X direction and its long sides are substantially parallel to the Y direction. Accordingly, the plurality of semiconductor chips 30 are stacked while being displaced in the short side direction of the semiconductor chips 30. The semiconductor chip 30 has an elongated shape when viewed from above. The semiconductor chip 30 may be disposed such that its short sides are substantially parallel to the Y direction and its long sides are substantially parallel to the X direction.

As Illustrated in FIG. 1, the stacks S2a, S2b are disposed to be aligned in the short side direction of the semiconductor chips 30.

Each of the stacks S2a, S2b has the semiconductor chips 30 stacked in two stages. The semiconductor chips 30 in the lowest stages of the stacks S2a, S2b are provided at different positions on the surface F10a. Note that the number of the stacked semiconductor chips 30 may be three or more.

The plurality of bonding wires 82 electrically connect the plurality of semiconductor chips 30 to one another. The stacks S2a, S2b are electrically connected to each other through the bonding wires 82. The bonding wires 82 unicursally connect the plurality of semiconductor chips 30 to one another, for example.

The thickness of the bonding layer 31 provided at the lower part of the semiconductor chip 30 in the lowest stage of the stack S2a is different from the thickness of the other bonding layers 31. More specifically, the bonding layer 31 provided at the lower part of the semiconductor chip 30 in the lowest stage of the stack S2a is thicker than the other bonding layers 31.

The bonding layer 31 provided at the lower part of the semiconductor chip 30 in the lowest stage of the stack S2a covers at least part of the semiconductor chip 40. Accordingly, the stack S2a and the semiconductor chip 40 can be disposed close to each other, and the package area can be made smaller.

The bonding layer 31 provided at the lower part of the semiconductor chip 30 in the lowest stage of the stack S2a covers at least part of the bonding wire 82 that electrically connects the semiconductor chip 30 in the lowest stage of the stack S2b to the wiring substrate 10. Accordingly, the stacks S2a, S2b can be disposed close to each other, and the package area can be made smaller.

As described above, according to the first embodiment, the thickness of the bonding layer 21 provided at the lower part of the semiconductor chip 20 in the lowest stage of the stack S1b is different from the thickness of the other bonding layers 21. The thickness of the bonding layer 31 provided at the lower part of the semiconductor chip 30 in the lowest stage of the stack S2a is different from the thickness of the other bonding layers 31. Accordingly, the semiconductor chips 20, 30 can be more appropriately disposed in the package.

In the first embodiment, the plurality of stacks S1a, S1b disposed at different positions on the surface F10a are electrically connected to each other through the bonding wires 81. The plurality of stacks S2a, S2b disposed at different positions on the surface F10a are electrically connected to each other through the bonding wires 82. Accordingly, multi-stage stacking is not performed, and a plurality of stacks which are electrically connected and are relatively low layers are provided.

As Illustrated in FIG. 2, the semiconductor chips 20, 30 whose ratio (aspect ratio) of the width of the long sides to the width of the short sides is high are used in some cases. As will be described later, even in the case where the semiconductor chips 20, 30 having a high aspect ratio are used, the semiconductor chips 20, 30 can be more appropriately disposed in the package. Note that the aspect ratio of the semiconductor chips 20, 30 illustrated in FIG. 2 is an example.

The ratio (aspect ratio) of the width of the long sides to the width of the short sides of the semiconductor chips 20, 30 is more than or equal to a predetermined value. The predetermined value is three, for example. For example, as the width of the short sides decreases, the aspect ratio increases. The predetermined value may be five or ten, for example.

Pads of the semiconductor chips 20 constituting the stack S1a are located on the right side of the chips (on one of the long sides) when viewed from above. Pads of the semiconductor chips 20 constituting the stack S1b are located on the left side of the chips (on one of the long sides that is closer to the stack S1a) when viewed from above.

When identical semiconductor chips are used for the stacks S1a and S1b, it is necessary to oppositely orient the semiconductor chips in the stacks S1a and S1b in order to achieve the above disposition. Specifically, it is necessary to turn the semiconductor chips 180° in the in-plane direction.

Therefore, different chips may be used for the semiconductor chips 20 constituting the stack S1a and the semiconductor chips 20 constituting the stack S1b. At this time, the semiconductor chips 20 constituting the stack S1b and the semiconductor chips 20 constituting the stack S1a may have the same in-chip configuration and may have the pads differently disposed.

The same applies to the stacks S2a and S2b.

Note that the thick bonding layers 21, 31 may be provided at the lower part of at least one of the semiconductor chips 20, 30 in the lowest stages.

The semiconductor chip 40 is not limited to flip-chip connection and may be connected by wire bonding. At this time, the thick bonding layers 21, 31 bury wires.

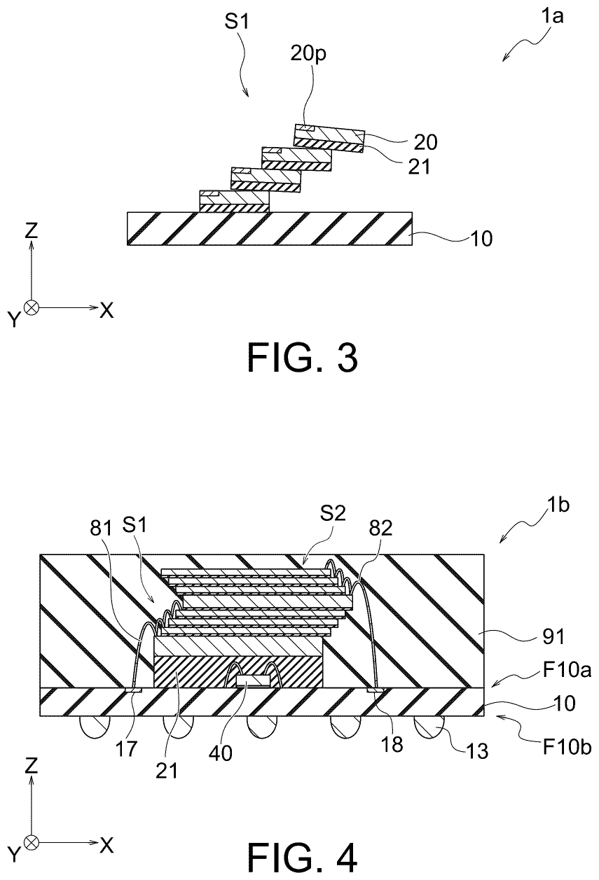

FIG. 3 is a cross sectional view illustrating an example of the configuration of a semiconductor device 1a according to a first comparative example of the first embodiment. The first comparative example of the first embodiment is different from the first embodiment in that the bonding layers 21 have the same thickness. Note that since a stack S1 will be described in detail with reference to FIG. 3, illustration of the configuration excluding the wiring substrate 10 and the stack S1 in FIG. 1 is omitted.

The semiconductor device 1a includes the stack S1. The stack S1 includes the semiconductor chips 20 stacked in four stages.

As the width of the short sides (in the X direction) of the semiconductor chip 20 decreases, that is, the aspect ratio increases, the semiconductor chips 20 at high stages are likely to be inclined with respect to the wiring substrate 10. This is because the area in which the lower semiconductor chips 20 support the upper semiconductor chips 20 decreases when the semiconductor chips 20 are die-bonded. As a result, it is difficult to stack the semiconductor chips 20 in high stages.

In contrast, in the first embodiment, the stacks S1a, S1b, S2a, and S2b which are lower layers than the stack S1 in FIG. 3 are disposed to be aligned in the short side direction of the semiconductor chips 20, 30. Accordingly, even in the case where the semiconductor chips 20, 30 having a high aspect ratio are used, the semiconductor chips 20, 30 can be more appropriately disposed. Accordingly, the semiconductor chips 20, 30 can be more appropriately disposed in the package.

FIG. 4 is a cross sectional view illustrating an example of the configuration of a semiconductor device 1b according to a second comparative example of the first embodiment. The second comparative example of the first embodiment is different from the first embodiment in that the aspect ratio of the semiconductor chips 20, 30 is relatively low.

The semiconductor device 1b includes the stacks S1, S2. The stack S1 has the semiconductor chips 20 stacked in four stages. The stack S2 has the semiconductor chips 30 stacked in four stages. The stack S1 is provided above the semiconductor chip 40, and the stack S2 is provided on the stack S1.

Since the aspect ratio of the semiconductor chips 20, 30 is relatively low, the width of the short sides of the semiconductor chips 20, 30 is relatively large. The semiconductor chip 40 is buried by the bonding layer 21 provided at the lower part of the semiconductor chip 20.

In contrast, since the aspect ratio of the semiconductor chips 20, 30 is relatively high in the first embodiment, the semiconductor chip 40 is not completely buried by the bonding layers 21, 31. Part of the semiconductor chip 40 is covered by the plurality of semiconductor chips 20, 30. Accordingly, the semiconductor chips 20, 30 can be more appropriately disposed in the package.

### First Modification of First Embodiment

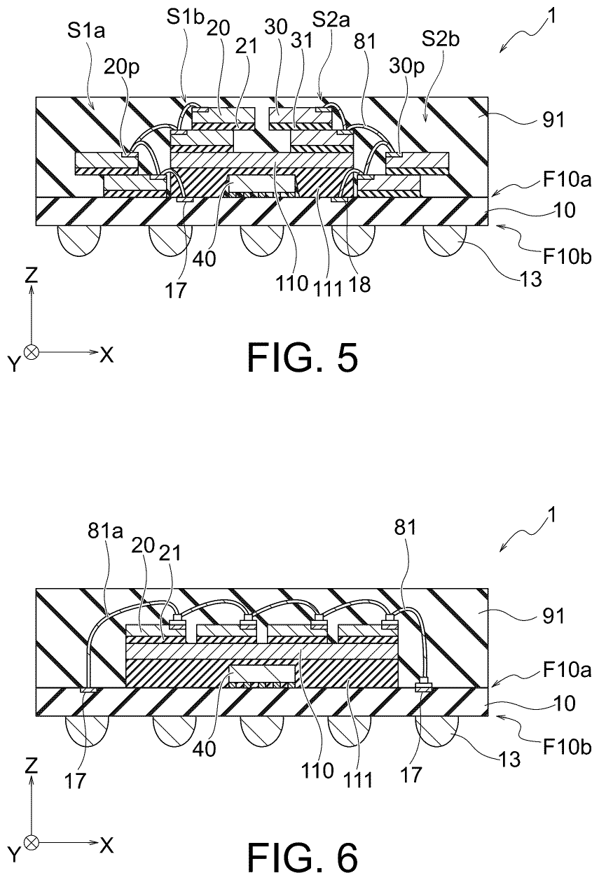

FIG. 5 is a cross sectional view illustrating an example of the configuration of the semiconductor device 1 according to a first modification of the first embodiment. The first modification of the first embodiment is different from the first embodiment in that a spacer 110 is provided above the semiconductor chip 40.

The semiconductor device 1 further includes the spacer 110 and a bonding layer 111.

The spacer 110 is provided above the semiconductor chip 40. The spacer 110 may include Si or may include resin such as polyimide (PI), for example.

The bonding layer 111 is provided at a lower part of the spacer 110.

The stacks S1b, S2a are provided on the spacer 110. The stacks S1b, S2a are disposed so as to be overlapped on at least part of the semiconductor chip 40 when viewed in the Z direction.

The semiconductor chip 40 is provided on the surface F10a so as to be covered (buried) by the bonding layer 111.

As in the first modification of the first embodiment, the spacer 110 may be provided above the semiconductor chip 40. With the semiconductor device 1 according to the first modification of the first embodiment, it is possible to obtain the same effects as in the first embodiment.

### Second Embodiment

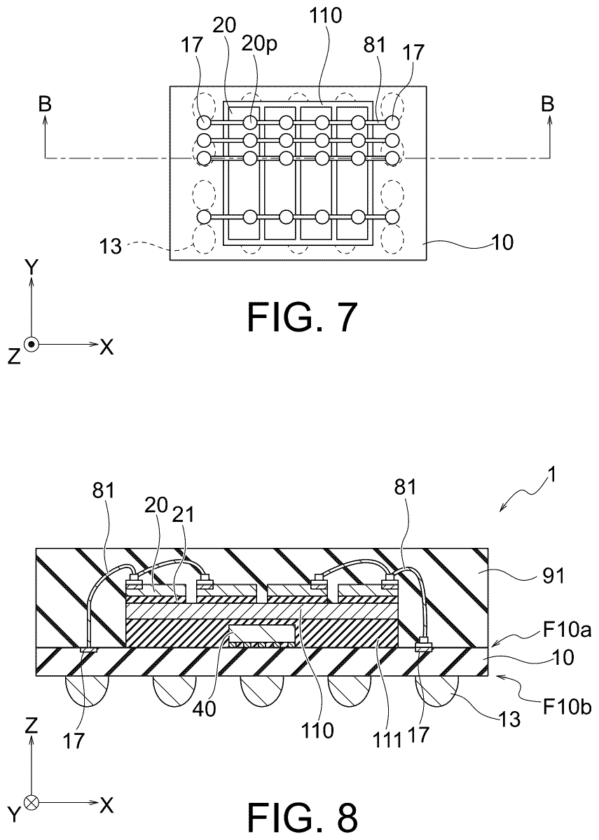

FIG. 6 is a cross sectional view illustrating an example of the configuration of the semiconductor device 1 according to a second embodiment. FIG. 7 is a top view illustrating the example of the configuration of the semiconductor device 1 according to the second embodiment. Line B-B in FIG. 7 indicates a cross section corresponding to the cross sectional view of FIG. 6. The second embodiment is different from the first embodiment in that the spacer 110 is provided and the semiconductor chips 20 are disposed to be aligned on the spacer 110.

Note that in the example illustrated in FIGS. 6 and 7, the semiconductor chips 30 are not illustrated.

The semiconductor device 1 further includes the spacer 110, the bonding layer 111, and a bonding wire 81a.

The spacer 110 is provided on the surface F10a. The spacer 110 may include Si or may include resin such as PI, for example.

The bonding layer 111 is provided at the lower part of the spacer 110.

The bonding wire 81a electrically connects the leftmost semiconductor chip 20 in FIG. 6 to the wiring substrate 10. The leftmost semiconductor chip 20 in FIG. 6 is supplied with a reference voltage (power/ground) from the bonding wire 81a.

The rightmost semiconductor chip 20 in FIG. 6 is supplied with a signal and the reference voltage (power/ground) from the wiring substrate 10 through the bonding wire 81. The leftmost semiconductor chip 20 is distant from a connection point between the rightmost semiconductor chip 20 and the wiring substrate 10. By providing the bonding wire 81a capable of supplying the reference voltage, the power supply can be enhanced.

The plurality of semiconductor chips 20 are provided at different positions on the spacer 110. That is, the plurality of semiconductor chips 20 are disposed to be aligned on the spacer 110. The plurality of semiconductor chips 20 are provided to be in contact with the upper surface (on the same surface) of the spacer 110 through the bonding layers 21.

The semiconductor chips 20 have a plurality of pads 20p to be connected to the bonding wires 81.

The bonding wires 81 electrically connect the plurality of semiconductor chips 20, which are in contact with the spacer 110 through the bonding layers 21, to one another.

The semiconductor chip 40 is provided on the surface F10a so as to be covered (buried) by the bonding layer 111.

In the example illustrated in FIG. 7, the four semiconductor chips 20 are disposed in the same orientation when viewed in the Z direction. That is, the plurality of semiconductor chips 20 are disposed such that the pads 20p are disposed in the same manner when viewed in the Z direction.

As the connection bumps 13, eight connection bumps 13 for input/output (I/O) (IO_0 to IO_7), for example, are provided.

As described above, according to the second embodiment, the plurality of semiconductor chips 20 are provided at different positions on the spacer 110. The bonding wires 81 electrically connect the plurality of semiconductor chips 20, which are in contact with the spacer 110 through the bonding layers 21, to one another. Accordingly, the semiconductor chips 20, 30 can be more appropriately disposed in the package.

As Illustrated in FIG. 7, the semiconductor chips 20 having a relatively high aspect ratio are used in some cases. As described with reference to FIG. 3, multi-stage stacking of the semiconductor chips 20 having a relatively high aspect ratio is difficult in some cases.

In contrast, in the second embodiment, the semiconductor chips 20 are not stacked. Accordingly, even in the case where the semiconductor chips 20, 30 having a high aspect ratio are used, the semiconductor chips 20, 30 can be more appropriately disposed. Accordingly, the semiconductor chips 20, 30 can be more appropriately disposed in the package.

Since the semiconductor chips 20 are not stacked, it is not necessary to cut the semiconductor chips 20, 30 thin, and the semiconductor chips 20, 30 can be made thicker. Accordingly, pick-up characteristics are improved, and chip breakage during pick-up or the like can be reduced. Since the cross-sectional structure in the package is simplified, a package warped shape is simplified. Accordingly, package warpage can be more easily controlled.

Since the semiconductor chips 20 have a small width in the short side direction, the bonding wires 81 that connect the semiconductor chips 20 can be prevented from increasing in length.

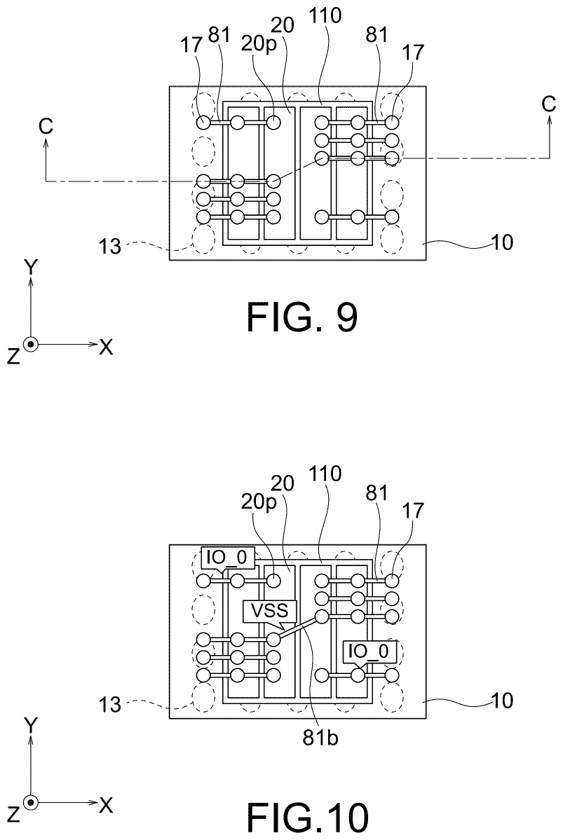

First modification of second embodiment FIG. 8 is a cross sectional view illustrating an example of the configuration of the semiconductor device 1 according to a first modification of the second embodiment. FIG. 9 is a top view illustrating an example of the configuration of the semiconductor device 1 according to the first modification of the second embodiment. Line C-C in FIG. 9 indicates a cross section corresponding to the cross sectional view of FIG. 8. The first modification of the second embodiment is different from the second embodiment in that some of the semiconductor chips 20 are provided in a different orientation.

In the example illustrated in FIG. 8, some of the four semiconductor chips 20 are disposed in a different orientation when viewed in the Z direction. More specifically, some of the four semiconductor chips 20 are disposed so as to have the pads 20p disposed in a reversed manner when viewed in the Z direction. The two semiconductor chips 20 on the left are disposed such that the orientation of the semiconductor chips 20 is turned (reversed) 180° with respect to the two semiconductor chips 20 on the right when viewed in the Z direction.

As the connection bumps 13, sixteen connection bumps 13 for I/O, for example, are provided. In the first modification of the second embodiment, connection for I/O is separated between the two semiconductor chips 20 on the left and the two semiconductor chips 20 on the right. In this case, the connection bumps for I/O twice those in the second embodiment in which the four semiconductor chips 20 are connected are provided. Accordingly, the semiconductor chips 20 can be operated in parallel. For example, the operation speed can be doubled although power consumption is doubled.

As in the first modification of the second embodiment, some of the semiconductor chips 20 may be disposed in a different orientation. With the semiconductor device 1 according to the first modification of the second embodiment, it is possible to obtain the same effects as in the second embodiment.

### Second Modification of Second Embodiment

FIG. 10 is a top view illustrating an example of the configuration of the semiconductor device 1 according to a second modification of the second embodiment. The second modification of the second embodiment is different from the first modification of the second embodiment in that a bonding wire 81b that connects the pads 20p for the reference voltage is provided.

The semiconductor device 1 further includes the bonding wire 81b. The bonding wire 81b electrically connects the respective pads 20p of the semiconductor chips 20 disposed to be turned (reversed) 180°. The bonding wire 81b is not connected to the pads 20p for signals such as I/O and DQ/DQS, but is connected to the pads 20p for the reference voltage (power/ground).

In the example illustrated in FIG. 10, the pads 20p for the reference voltage (ground VSS) are electrically connected between the two semiconductor chips 20 on the left and the two semiconductor chips 20 on the right through the bonding wire 81b. On the other hand, the pads 20p (IO_0) for signals are not connected between the two semiconductor chips 20 on the left and the two semiconductor chips 20 on the right.

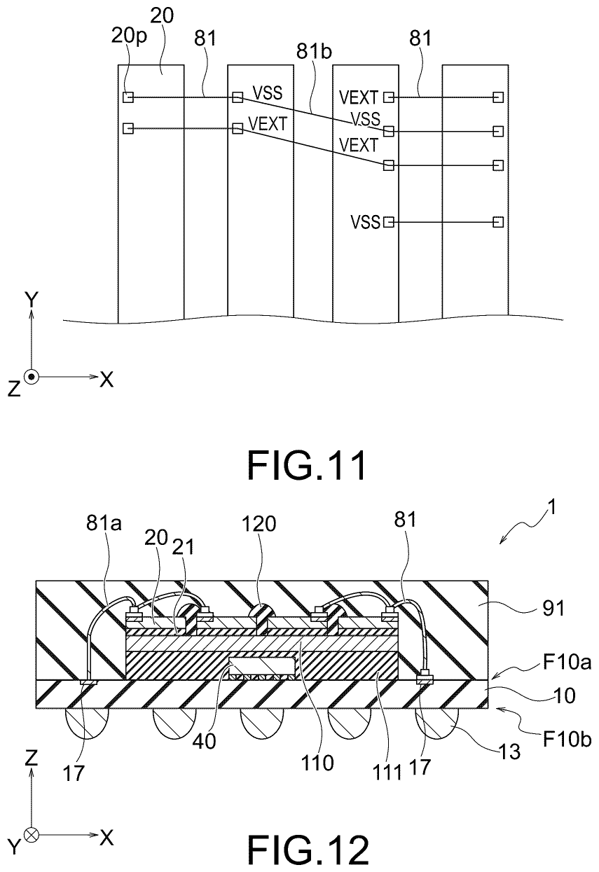

FIG. 11 is a top view illustrating an example of connection of the bonding wires 81, 81b in the second modification of the second embodiment. Note that FIG. 11 illustrates the pads 20p for the reference voltage (power supply VEXT/ground VSS), and the pads 20p for signals are omitted. Although illustration is omitted, the pads 20p for signals are disposed between the pads 20p for the power supply VEXT/ground VSS.

As Illustrated in FIG. 11, connection through the bonding wire 81b is difficult in some cases depending on the disposition of the pads 20p. For example, the pads 20p for the power supply VEXT of the semiconductor chips 20 on the left are not disposed in some cases at positions opposite to the pads 20p for the power supply VEXT of the semiconductor chips 20 on the right. Examples thereof include a case in which identical chips are used for the semiconductor chips 20 on the right and on the left and the semiconductor chips 20 on the right are turned 180° with respect to the semiconductor chips 20 on the left. In this case, the pad 20p for the power supply VEXT of the semiconductor chip 20 on the right is not connected through the bonding wire 81b in some cases. Similarly, the pad 20p for the ground VSS of the semiconductor chip 20 on the left is not disposed in some cases at a position opposite to the pad 20p for the ground VSS of the semiconductor chip 20 on the right. In this case, the pad 20p for the ground VSS of the semiconductor chip 20 on the right is not connected through the bonding wire 81b in some cases.

As in the second modification of the second embodiment, the bonding wire 81b that connects the pads 20p for the reference voltage to each other may be provided. With the semiconductor device 1 according to the second modification of the second embodiment, it is possible to obtain the same effects as in the first modification of the second embodiment.

### Third Modification of Second Embodiment

FIG. 12 is a cross sectional view illustrating an example of the configuration of the semiconductor device 1 according to a third modification of the second embodiment. The third modification of the second embodiment is different from the first modification of the second embodiment in that members 120 are provided among the semiconductor chips 20.

Note that in the example illustrated in FIG. 12, some of the semiconductor chips 20 are disposed in a different orientation. However, all the semiconductor chips 20 may be disposed in the same orientation.

The semiconductor device 1 further includes the members 120. The member 120 is provided to fill the gap between the semiconductor chips 20. The member 120 includes resin, for example.

As in the third modification of the second embodiment, the members 120 may be provided among the semiconductor chips 20. With the semiconductor device 1 according to the third modification of the second embodiment, it is possible to obtain the same effects as in the first modification of the second embodiment.

### Fourth Modification of Second Embodiment

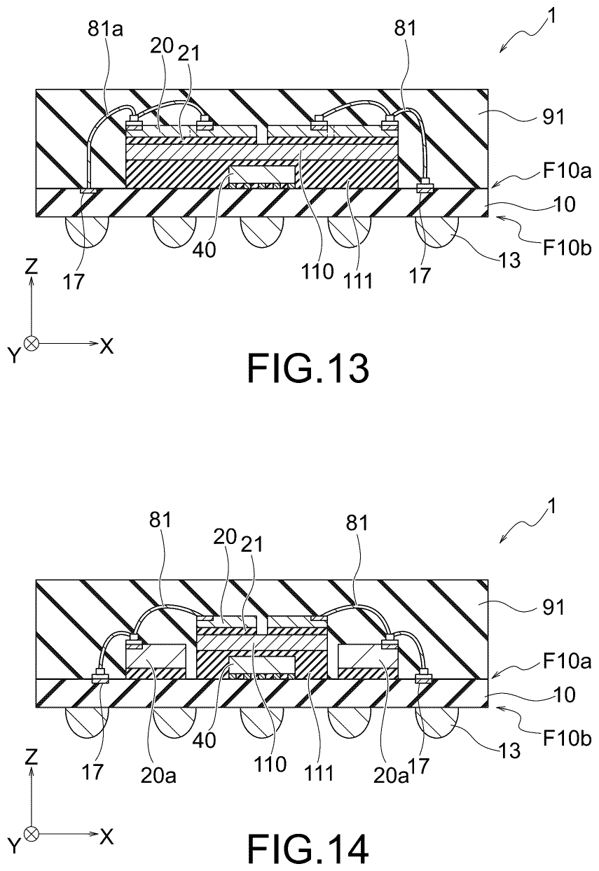

FIG. 13 is a cross sectional view illustrating an example of the configuration of the semiconductor device 1 according to a fourth modification of the second embodiment. The fourth modification of the second embodiment is different from the first modification of the second embodiment in that some of the semiconductor chips 20 are not diced (singulated).

The two semiconductor chips 20 on the left illustrated in FIG. 13 are not diced. Similarly, the two semiconductor chips 20 on the right are not diced. The two semiconductor chips 20 are cut out from a wafer while being connected and are mounted on the wiring substrate 10. Accordingly, the process can further be simplified.

As in the fourth modification of the second embodiment, some of the semiconductor chips 20 may not be diced (singulated). With the semiconductor device 1 according to the fourth modification of the second embodiment, it is possible to obtain the same effects as in the first modification of the second embodiment.

### Fifth Modification of Second Embodiment

FIG. 14 is a cross sectional view illustrating an example of the configuration of the semiconductor device 1 according to a fifth modification of the second embodiment. The fifth modification of the second embodiment is different from the second embodiment in that semiconductor chips 20a are further provided on the wiring substrate 10.

The semiconductor device 1 further includes the semiconductor chips 20a. The semiconductor chips 20a are provided at positions on the surface F10a different from the spacer 110. The semiconductor chips 20a are provided to be adjacent to the spacer 110, for example. The shape of the semiconductor chips 20a is substantially the same as the shape of the semiconductor chips 20, for example.

The bonding wire 81 electrically connects the semiconductor chip 20, which is in contact with the spacer 110 through the bonding layer 21, to the semiconductor chip 20a.

Since the semiconductor chip 20a has a small width in the short side direction, the bonding wire 81 that connects the semiconductor chip 20 and the semiconductor chip 20a can be prevented from increasing in length.

As in the fifth modification of the second embodiment, the semiconductor chips 20a may further be provided on the wiring substrate 10. With the semiconductor device 1 according to the fifth modification of the second embodiment, it is possible to obtain the same effects as in the second embodiment.

### Sixth Modification of Second Embodiment

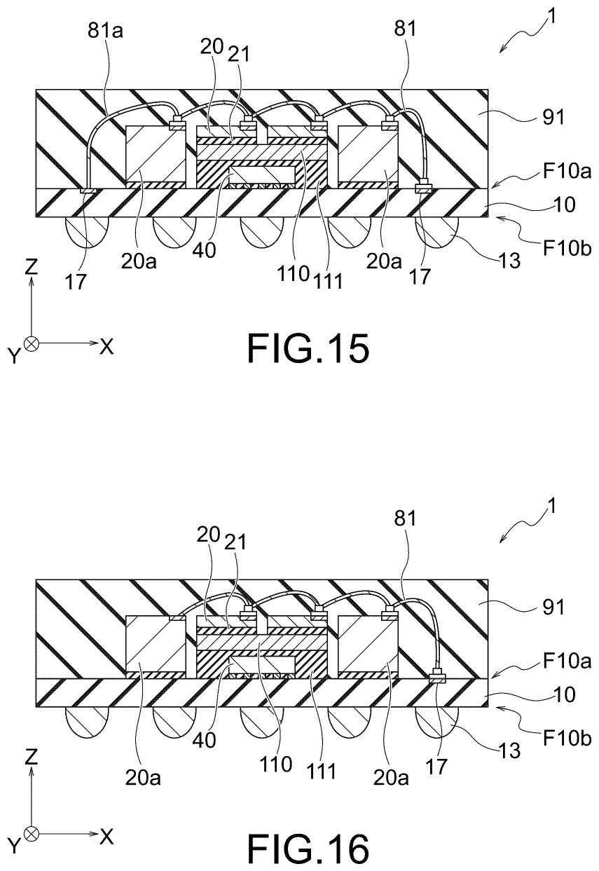

FIG. 15 is a cross sectional view illustrating an example of the configuration of the semiconductor device 1 according to a sixth modification of the second embodiment. The sixth modification of the second embodiment is different from the fifth modification of the second embodiment in that the semiconductor chips 20a are thick.

The upper surface of the semiconductor chip 20a is at a height substantially the same as the height of the upper surface of the semiconductor chip 20. Accordingly, the bonding wire 81 that connects the semiconductor chip 20 and the semiconductor chip 20a and the bonding wire 81 that connects the semiconductor chips 20 to each other can be made substantially equal in length.

As in the sixth modification of the second embodiment, the semiconductor chip 20a may be thick. With the semiconductor device 1 according to the sixth modification of the second embodiment, it is possible to obtain the same effects as in the fifth modification of the second embodiment.

### Seventh Modification of Second Embodiment

FIG. 16 is a cross sectional view illustrating an example of the configuration of the semiconductor device 1 according to a seventh modification of the second embodiment. The seventh modification of the second embodiment is different from the sixth modification of the second embodiment in that the bonding wire 81a is not provided.

As in the seventh modification of the second embodiment, the bonding wire 81a may not be provided. With the semiconductor device 1 according to the seventh modification of the second embodiment, it is possible to obtain the same effects as in the sixth modification of the second embodiment.

### Eighth Modification of Second Embodiment

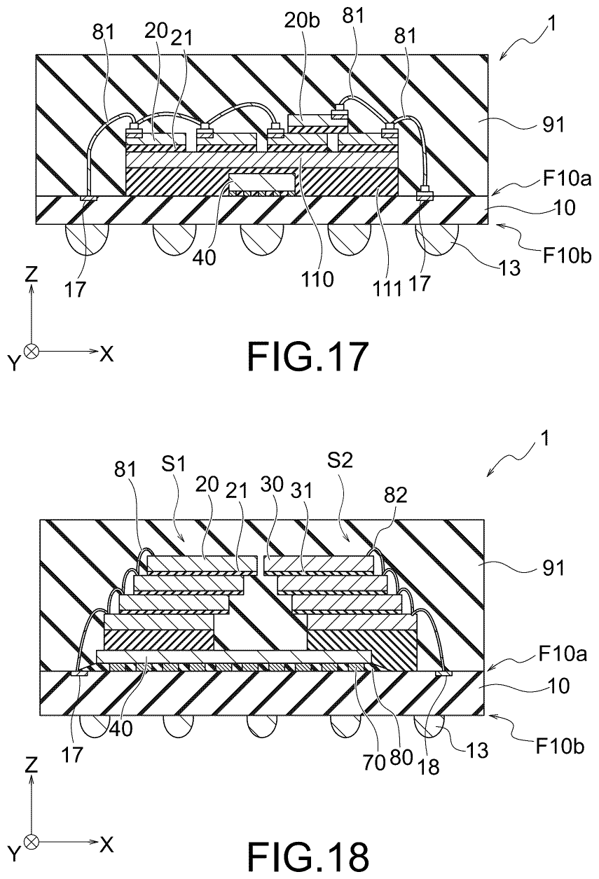

FIG. 17 is a cross sectional view illustrating an example of the configuration of the semiconductor device 1 according to an eighth modification of the second embodiment. The eighth modification of the second embodiment is different from the first modification of the second embodiment in that a semiconductor chip 20b is further provided on the semiconductor chips 20.

The semiconductor device 1 further includes the semiconductor chip 20b. The semiconductor chip 20b is provided on the semiconductor chips 20. The semiconductor chip 20b is disposed so as to extend over the plurality of semiconductor chips 20, for example. The shape of the semiconductor chip 20b is substantially the same as the shape of the semiconductor chip 20, for example.

The bonding wire 81 electrically connects the semiconductor chip 20 and the semiconductor chip 20b.

As in the eighth modification of the second embodiment, the semiconductor chip 20b may further be provided on the semiconductor chips 20. With the semiconductor device 1 according to the eighth modification of the second embodiment, it is possible to obtain the same effects as in the first modification of the second embodiment.

### Third Embodiment

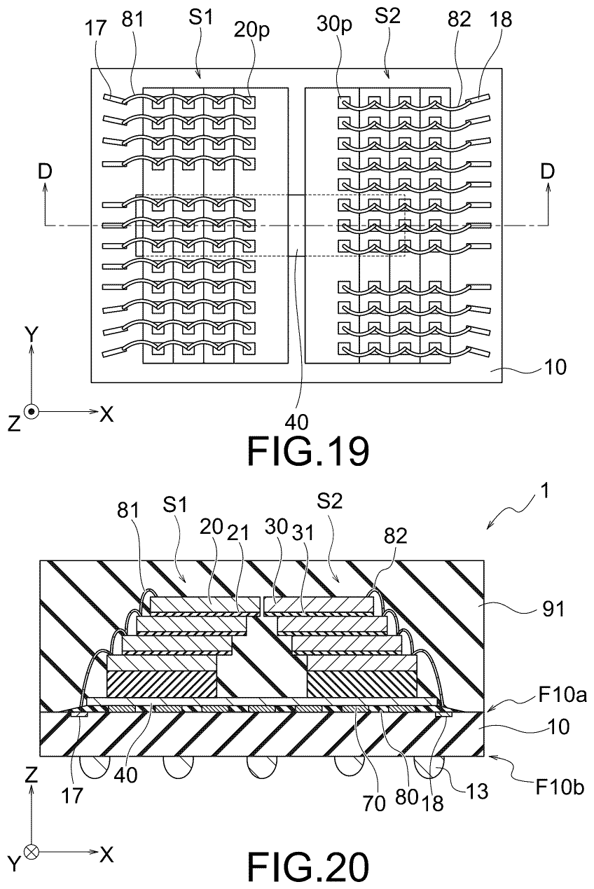

FIG. 18 is a cross sectional view illustrating an example of the configuration of the semiconductor device 1 according to a third embodiment. FIG. 19 is a top view illustrating an example of the configuration of the semiconductor device 1 according to the third embodiment. Line D-D in FIG. 19 indicates a cross section corresponding to the cross sectional view of FIG. 18.

The semiconductor device 1 includes the stacks S1, S2. The stack S1 has the semiconductor chips 20 stacked in four stages. The stack S2 has the semiconductor chips 30 stacked in four stages. The stacks S1, S2 are provided at different positions on the surface F10a. More specifically, the semiconductor chips 20, 30 in the lowest stages are provided at different positions on the surface F10a.

The semiconductor chip 40 is provided on the surface F10a so as to be at least partially covered by the plurality of bonding layers 21. Since the aspect ratio of the semiconductor chips 20, 30 is relatively high in the example illustrated in FIG. 19, the long side (in the X direction) of the semiconductor chip 40 protrudes in the X direction from both sides of the stack S1 when viewed in the Z direction.

The bonding layers 21, 31 covering the semiconductor chip 40 and provided at the lower parts of the semiconductor chips 20, 30 in the lowest stages may be thicker than, and may be different in material from, the other bonding layers 21, 31. It is preferable that the bonding layers 21, 31 provided at the lower parts of the semiconductor chips 20, 30 in the lowest stages should be soft so as to easily cover the semiconductor chip 40, for example.

As described above, according to the third embodiment, the semiconductor chip 40 is provided on the surface F10a so as to be at least partially covered by the plurality of bonding layers 21, 31. Accordingly, the semiconductor chips 20, 30 can be more appropriately disposed in the package. The package area can be made smaller.

Note that the semiconductor chip 40 has a rectangular shape when viewed in the Z direction. A rectangle has a longer outer periphery than a square having the same area. Accordingly, in the case where the semiconductor chip 40 is connected to the wiring substrate 10 by wire bonding, it is preferable that the semiconductor chip 40 should have a rectangular shape when viewed in the Z direction.

In the case where the semiconductor chips 20 have a relatively low aspect ratio as described with reference to FIG. 4, the semiconductor chip 40 is buried by the bonding layer 21 provided under the semiconductor chip 20.

In contrast, since the aspect ratio of the semiconductor chips 20, 30 is relatively high in the third embodiment, part of the semiconductor chip 40 is covered by the plurality of stacks S1, S2. Accordingly, the semiconductor chips 20, 30 can be more appropriately disposed in the package.

### First Modification of Third Embodiment

FIG. 20 is a cross sectional view illustrating an example of the configuration of the semiconductor device 1 according to a first modification of the third embodiment. The first modification of the third embodiment is different from the third embodiment in that the long side of the semiconductor chip 40 has a different width.

In the example illustrated in FIG. 20, the long side (in the X direction) of the semiconductor chip 40 protrudes in the X direction from both sides of each of the stacks S1, S2 when viewed in the Z direction.

As in the first modification of the third embodiment, the long side of the semiconductor chip 40 may have a different width. With the semiconductor device 1 according to the first modification of the third embodiment, it is possible to obtain the same effects as in the third embodiment.

### Second Modification of Third Embodiment

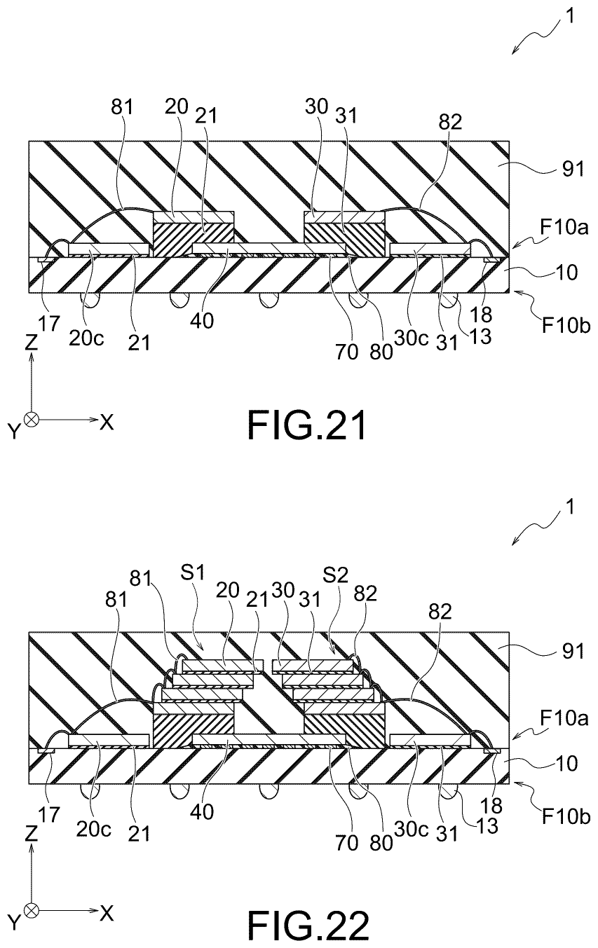

FIG. 21 is a cross sectional view illustrating an example of the configuration of the semiconductor device 1 according to a second modification of the third embodiment. The second modification of the third embodiment is different from the third embodiment in that semiconductor chips 20c, 30c are further provided on the wiring substrate 10.

Note that in the example illustrated in FIG. 21, the semiconductor chips 20, 30 are each provided in a single stage.

The semiconductor device 1 further includes the semiconductor chips 20c, 30c. The semiconductor chips 20c, 30c are provided at positions on the surface F10a different from the semiconductor chips 20, 30, and 40. The shape of the semiconductor chips 20c, 30c is substantially the same as the shape of the semiconductor chips 20, 30, for example.

The semiconductor chip 20c is electrically connected to the semiconductor chip 20 through the bonding wire 81. The semiconductor chip 20c is provided to be adjacent to the semiconductor chip 20, for example. Since the semiconductor chips 20, 20c have a relatively high aspect ratio, it is easy to dispose the semiconductor chips 20, 20c to be aligned with each other.

The semiconductor chip 30c is electrically connected to the semiconductor chip 30 through the bonding wire 82. The semiconductor chip 30c is provided to be adjacent to the semiconductor chip 30, for example. Since the semiconductor chips 30, 30c have a relatively high aspect ratio, it is easy to dispose the semiconductor chips 30, 30c to be aligned with each other.

Since the semiconductor chip 20c has a small width in the short side direction, the bonding wire 81 that connects the semiconductor chip 20 and the semiconductor chip 20c can be prevented from increasing in length. Since the semiconductor chip 30c has a small width in the short side direction, the bonding wire 82 that connects the semiconductor chip 30 and the semiconductor chip 30c can be prevented from increasing in length.

As in the second modification of the third embodiment, the semiconductor chips 20c, 30c may further be provided on the wiring substrate 10. With the semiconductor device 1 according to the second modification of the third embodiment, it is possible to obtain the same effects as in the third embodiment.

### Third Modification of Third Embodiment

FIG. 22 is a cross sectional view illustrating an example of the configuration of the semiconductor device 1 according to a third modification of the third embodiment. The third modification of the third embodiment is different from the second modification of the third embodiment in that the semiconductor chips 20, 30 are stacked. That is, the third modification of the third embodiment is also a combination of the third embodiment and the second modification of the third embodiment.

In the example illustrated in FIG. 22, the semiconductor chip 20c is electrically connected to the semiconductor chip 20 in the lowest stage through the bonding wire 81. The semiconductor chip 30c is electrically connected to the semiconductor chip 30 in the lowest stage through the bonding wire 82.

As in the third modification of the third embodiment, the semiconductor chips 20, 30 may be stacked. With the semiconductor device 1 according to the third modification of the third embodiment, it is possible to obtain the same effects as in the second modification of the third embodiment.

### Fourth Modification of Third Embodiment

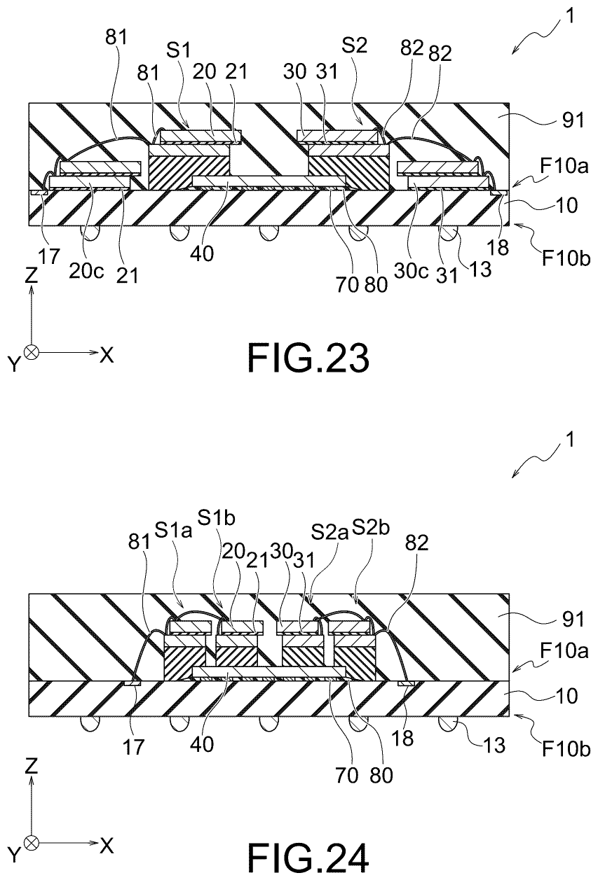

FIG. 23 is a cross sectional view illustrating an example of the configuration of the semiconductor device 1 according to a fourth modification of the third embodiment. The fourth modification of the third embodiment is different from the third modification of the third embodiment in that the semiconductor chips 20c, 30c are stacked.

In the example illustrated in FIG. 23, the semiconductor chips 20, 20c, 30, and 30c are each provided in two stages. The semiconductor chip 20c in the second stage is electrically connected to the semiconductor chip 20 in the lowest stage through the bonding wire 81. The semiconductor chip 30c in the second stage is electrically connected to the semiconductor chip 30 in the lowest stage through the bonding wire 82.

As in the fourth modification of the third embodiment, the semiconductor chips 20c, 30c may be stacked. With the semiconductor device 1 according to the fourth modification of the third embodiment, it is possible to obtain the same effects as in the third modification of the third embodiment.

### Fifth Modification of Third Embodiment

FIG. 24 is a cross sectional view illustrating an example of the configuration of the semiconductor device 1 according to a fifth modification of the third embodiment. The fifth modification of the third embodiment is different from the third embodiment in that the number of the semiconductor chips 20, 30 that cover the semiconductor chip 40 is different.

The semiconductor device 1 includes the stacks S1a, S1b, S2a, and S2b. The stacks S1a, S1b, S2a, and S2b are provided at different positions on the surface F10a.

Each of the stacks S1a, S1b has the semiconductor chips 20 stacked in two stages. The stacks S1a, S1b are electrically connected to each other through the bonding wire 81.

Each of the stacks S2a, S2b has the semiconductor chips 30 stacked in two stages. The stacks S2a, S2b are electrically connected to each other through the bonding wire 82.

The semiconductor chip 40 is provided on the surface F10a so as to be at least partially covered by the bonding layers 21, 31 of the stacks S1a, S1b, S2a, and S2b.

As in the fifth modification of the third embodiment, the number of the semiconductor chips 20, 30 that cover the semiconductor chip 40 may be changed. With the semiconductor device 1 according to the fifth modification of the third embodiment, it is possible to obtain the same effects as in third embodiment.

In the above described embodiments, semiconductor chips having an aspect ratio of more than or equal to three and less than five can be appropriately disposed. Semiconductor chips having an aspect ratio of more than or equal to five and less than ten can be appropriately disposed. Semiconductor chips having an aspect ratio of more than or equal to ten and less than fifteen can be appropriately disposed.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor device comprising:
a substrate having a first surface;
a first stack having a plurality of first semiconductor chips;
a second stack provided at a position different from the first stack in an in-plane direction of the first surface and having a plurality of second semiconductor chips;
a first bonding layer provided at a lower part of each of the plurality of first semiconductor chips;
a second bonding layer provided at a lower part of each of the plurality of second semiconductor chips;
a first wire configured to electrically connect the first semiconductor chips and the second semiconductor chips to one another; and
a second wire configured to electrically connect the substrate and the second semiconductor chips, wherein
the first bonding layer provided at the lower part of the first semiconductor chip in a lowest stage has a thickness different from the thickness of the other first bonding layers.

2. The semiconductor device according to claim 1, further comprising a third semiconductor chip provided on the first surface, wherein
the first bonding layer having the thickness different from the thickness of the other first bonding layers covers at least part of the third semiconductor chip.

3. The semiconductor device according to claim 1, wherein the first bonding layer having the thickness different from the thickness of the other first bonding layers covers at least part of the second wire.

4. The semiconductor device according to claim 1, wherein
the first semiconductor chips and the second semiconductor chips have an elongated shape when viewed in a direction substantially orthogonal to the first surface,
a plurality of pads provided for the first semiconductor chips are provided along one of two long sides, and
a plurality of pads provided for the second semiconductor chips are provided along one of two long sides that is closer to the first semiconductor chips.

5. A semiconductor device comprising:
a substrate having a first surface;
a spacer provided on the first surface;
a first semiconductor chip provided on the spacer;
a second semiconductor chip provided on the spacer and provided so as not to be overlapped on the first semiconductor chip when viewed in a direction substantially orthogonal to the first surface;
a first bonding layer provided at a lower part of the first semiconductor chip;
a second bonding layer provided at a lower part of the second semiconductor chip;
a third bonding layer provided at a lower part of the spacer;
a third semiconductor chip provided on the first surface so as to be covered by the third bonding layer; and
a first wire configured to electrically connect at least one of the first semiconductor chip and the second semiconductor chip to the substrate.

6. The semiconductor device according to claim 5, wherein
the first semiconductor chip has a plurality of first pads to be connected to the first wire or a second wire configured to electrically connect the first semiconductor chip and the second semiconductor chip,
the second semiconductor chip has a plurality of second pads to be connected to the first wire or the second wire, and
when viewed in a direction substantially orthogonal to the first surface, the first semiconductor chip has an elongated shape, the plurality of first pads are provided along one of two long sides, the second semiconductor chip has an elongated shape, and the plurality of second pads are provided along one of two long sides that is more distant from the first semiconductor chip.

7. The semiconductor device according to claim 5, wherein
the first semiconductor chip has a plurality of first pads to be connected to the first wire or a second wire configured to electrically connect the first semiconductor chip and the second semiconductor chip,
the second semiconductor chip has a plurality of second pads to be connected to the first wire or the second wire,
when viewed in the direction substantially orthogonal to the first surface, the first semiconductor chip has an elongated shape, and the plurality of first pads are provided along one of two long sides, and
the second semiconductor chip has an elongated shape, and the plurality of second pads are provided along one of two long sides that is closer to the first semiconductor chip.

8. The semiconductor device according to claim 5, further comprising:
a fourth semiconductor chip provided on the first surface so as not to be overlapped on the spacer when viewed in the direction substantially orthogonal to the first surface; and
a third wire configured to electrically connect the first semiconductor chip, which is in contact with the spacer through the first bonding layer, to the fourth semiconductor chip.

9. A semiconductor device comprising:
a substrate having a first surface;
a plurality of first semiconductor chips provided on the first surface;
a plurality of first bonding layers provided at lower parts of each of the plurality of first semiconductor chips; and
a second semiconductor chip provided on the first surface so as to be at least partially covered by at least one of the plurality of first bonding layers.

10. The semiconductor device according to claim 9, further comprising a fifth semiconductor chip provided on the first surface so as not to be overlapped on the first semiconductor chips and the second semiconductor chip when viewed in a direction substantially orthogonal to the first surface, the fifth semiconductor chip being electrically connected to one of the first semiconductor chips through a wire.

11. The semiconductor device according to claim 1, wherein a ratio of a width of long sides to a width of short sides of the first semiconductor chips is more than or equal to three and less than five.

12. The semiconductor device according to claim 1, wherein a ratio of a width of long sides to a width of short sides of the first semiconductor chips is more than or equal to five and less than ten.

13. The semiconductor device according to claim 1, wherein a ratio of a width of long sides to a width of short sides of the first semiconductor chips is more than or equal to ten and less than fifteen.

14. The semiconductor device according to claim 5, wherein a ratio of a width of long sides to a width of short sides of the first semiconductor chips is more than or equal to three and less than five.

15. The semiconductor device according to claim 9, wherein a ratio of a width of long sides to a width of short sides of the first semiconductor chips is more than or equal to three and less than five.

16. The semiconductor device according to claim 5, wherein a ratio of a width of long sides to a width of short sides of the first semiconductor chips is more than or equal to five and less than ten.

17. The semiconductor device according to claim 9, wherein a ratio of a width of long sides to a width of short sides of the first semiconductor chips is more than or equal to five and less than ten.

18. The semiconductor device according to claim 5, wherein a ratio of a width of long sides to a width of short sides of the first semiconductor chips is more than or equal to ten and less than fifteen.

19. The semiconductor device according to claim 9, wherein a ratio of a width of long sides to a width of short sides of the first semiconductor chips is more than or equal to ten and less than fifteen.
